(19) United States
(12) Patent Application Publication
(10) Pub. No.: US 2002/0038999 A1
(43) Pub. Date: Apr. 4, 2002

(54) High resistance conductive polymers for use in high efficiency pixellated organic electronic devices

(76) Inventors: Yong Cao, Goleta, CA (US); Chi Zhang, Goleta, CA (US)

Correspondence Address: E I DU PONT DE NEMOURS AND COMPANY, LEGAL DEPARTMENT - PATENTS, 1007 MARKET STREET, WILMINGTON, DE, 19898, US

(21) Appl. No.: 09/878,570

(22) Filed: Jun. 11, 2001

Related U.S. Application Data
(63) Continuation-in-part of application No. 09/725,694, filed on Nov. 29, 2000.
(60) Provisional application No. 60/212,736, filed on Jun. 20, 2000.

(51) Int. Cl. H01J 1/62

(52) U.S. Cl. 313/503

(57) ABSTRACT

In pixellated electronic devices such as polymer emissive displays (PEDs), good operating lifetime is achieved through the use of a high resistivity buffer layer of conductive organic polymer between the anode layer and the photoactive layer. The improved high resistivity conductive layer gives long lifetime with reduced or no cross-talk and current leakage between neighboring pixels.

### FIELD OF THE INVENTION

This invention relates to the formulation of high resistivity conjugated polymers in conductive forms for use in high efficiency pixellated organic electronic devices, such as emissive displays. The high resisvitiy layer provides excellent hole injection, prevents electrical shorts, enhances the device lifetime and avoids inter-pixel current leakage.

### BACKGROUND OF THE INVENTION

Light emitting diodes (LEDs) fabricated with conjugated organic polymer layers have attracted attention due to their potential for use in display technology [J. H. Burroughs, D. D. C. Bradley, A. R. Brown, R. N. Marks, K. Mackay, R. H. Friend, P. L. Burns, and A. B. Holmes, Nature 347, 539 (1990); D. Braun and A. J. Heeger, Appl. Phys. Lett. 58, 1982 (1991)]. Patents covering polymer LEDs include the following: R. H. Friend, J. H. Burroughs and D. D. Bradley, U.S. Pat. No. 5,247,190; A. J. Heegr and D. Braun, U.S. Pat. Nos. 5,408,109 and 5,869,350. These references as well as all additional articles, patents and patent applications referenced herein are incorporated by reference.

In their most elementary form, these diodes employ a layer of conjugated organic polymer bounded on one side by a hole-injecting electrode (anode) and on the other by an electron-injecting electrode (cathode), one of which is transparent to the light produced in the conjugated polymer layer when a potential is applied across it.

In many applications, especially in displays, arrays of these diodes are assembled. In these applications, there is typically a unit body of active polymer and the electrodes are patterned to provide the desired plurality of pixels in the array. With arrays based on a unit body of active polymer and patterned electrodes there is a need to minimize interference or “cross talk” among adjacent pixels. This need has also been addressed by varying the nature of the contacts between the active polymer body and the electrodes.

The desire to improve operating life and efficiency is often seemingly at cross purposes with the desire to minimize cross talk. High efficiency and long operating life are promoted by the use of high conductivity contacts with the active material layer. Cross talk is minimized when the resistance between adjacent pixels is high. Structures which favor high conductivity and thus high efficiency and long operating life are contrary to the conditions preferred for low cross talk.

In U.S. Pat. No. 5,723,873 it is disclosed that it is advantageous to place a layer of polyaniline (PANI) in its conductive emeraldine salt PANI(ES) form between the hole-injecting electrode and the layer of active material to increase diode efficiency and to lower the diode's turn on voltage.

Using a layer of PANI(ES), or blends comprising PANI(ES), directly between the ITO and the light-emitting polymer layer, C. Zhang, G. Yu and Y. Cao (U.S. Pat. No. 5,798,170) demonstrated polymer LEDs with long operating lifetimes.

Despite the advantages of using PANI(ES) in polymer LEDs (as described in U.S. Pat. No. 5,798,170), the low electrical resisitivity typical of PANI(ES) inhibits the use of PANI(ES) in pixelated displays. For use in pixellated displays, the PANI(ES) layer should have a high electrical sheet resistance, otherwise lateral conduction causes cross-talk between neighboring pixels. The resulting inter-pixel current leakage significantly reduces the power efficiency and limits both the resolution and the clarity of the display.

Making the PANI sheet resistance higher by reducing the film thickness is not a good option since thinner films give lower manufacturing yield caused by the formation of electrical shorts. This is demonstrated clearly in FIG. 1, which shows the fraction of “leaky” pixels in a 96×64 array vs thickness of the PANI(ES) polyblend layer. Thus, to avoid shorts it is necessary to use a relatively thick PANI(ES) layer with thickness ˜200 nm.

With a film thickness of 200 nm or greater, the electrical resistivity of the PANI(ES) layer should be greater than or equal to 10⁴ ohm-cm to avoid crosstalk and inter-pixel current leakage. Values in excess of 10⁵ ohm-cm are preferred. Even at 10⁵ ohm-cm, there is some residual current leakage and consequently some reduction in device efficiency. Thus, values of approximately 10⁶ ohm-cm are even more preferred. Values greater than 10⁷ ohm-cm will lead to a significant voltage drop across the injection/buffer layer and therefore should be avoided. To achieve high resistivity PANI(ES) materials with resitivities in the desired range requires reformulation of the PANI(ES).

Thus, there is a need for a formulation of high resistivity conductive polymers such as PANI(ES) for use in high efficiency pixelated polymer emissive displays. Conductive polymers with resisitivity greater than 10⁴ ohm-cm is preferred; more preferably in excess of 10⁵ ohm-cm; and still more preferred in excess of 10⁶ ohm-cm. To be useful in polymer emissive displays, the high resisitivity conductive polymer layer should give long lifetime without significant current leakage between neighboring pixels.

### SUMMARY OF THE INVENTION

One aspect of the invention relates to an electronic device having at least the following components: a layer of electroactive conjugated organic polymer bounded on one side by a hole-injecting anode and on the other by a electron-injecting cathode, and a layer of conductive organic polymer having a resistivity of at least about 10⁴ ohms-cm between the anode and the layer of electroactive organic material.

Another aspect of the invention relates to a method for preparing an electronic device, the steps involving at least the following steps: depositing a layer of electroactive conjugated organic polymer on a patterned hole-injecting anode and thereafter depositing a patterned electron-injecting cathode on the layer of electroactive conjugated organic polymer, and depositing a high resistivity layer of conductive organic polymer onto the anode before the layer of electroactive conjugated organic polymer is deposited, wherein the layer of conductive organic polymer has a resistivity of at least about 10⁴ ohms-cm.

As used herein, the term “photoactive” organic material refers to any organic material that exhibits the electroactivity of electroluminescence and/or photosensitivity. The term “charge” when used to refer to charge injection/transport refers to one or both of hole and electron transport/injection, depending upon the context. The terms “conductivity” and “bulk conductivity” are used interchangeably, the value of which is provided in the unit of Siemens per centimeter (S/cm). In addition, the terms “surface resistivity” and “sheet resistance” are used interchangeably to refer to the resistance value that is a function of sheet thickness for a given material, the value of which is provided in the unit of ohm per square (ohm/sq). Also, the terms “bulk resistivity” and “electrical resistivity” are used interchangeably to refer to the resistivity that is a basic property of a specific materials (i.e., does not change with the dimension of the substance), the value of which provided in the unit of ohm-centimeter (ohm-cm). Electrical resistivity value is the inverse value of conductivity.

### BRIEF DESCRIPTION OF THE DRAWINGS

Certain embodiments of this invention will be described with reference being made to the drawings. In these drawings:

FIG. 1 is a graph which shows the fraction of “leaky” pixels (in a 96×64 array) vs thickness of the PANI(ES) layer.

FIG. 2 is a schematic diagram of the architecture of a passively addressed, pixelated, polymer LED display.

FIG. 3 is a graph which shows the dependence of the conductivity of PANI(ES) polyblends on PANI(ES)-PAAMPSA content.

FIG. 4 is a graph which shows the light output and external quantum efficiency for a device fabricated with the PANI(ES)-PAAMPSA buffer layer.

FIG. 5 is a graph which shows the stress induced degradation of a device with PANI(ES)-PAAMPSA layer at 85° C.

FIG. 6 is a graph which shows the stress induced degradation of devices with PANI(ES)-PAAMPSA buffer layer at room temperature.

FIG. 7 is a graph which shows the stress induced degradation of a device with a PANI(ES) PAAMPSA blend (Example 9) as the buffer layer; the data were obtained with the device at 70° C.

FIG. 8 shows photographs of three passively addressed displays (96×64) that were identical in every respect except that the display in FIG. 8a had a low resistance PEDT layer (resistivity is ˜200 ohm-cm), while the display in FIG. 8b had a PANI(ES) polyblend layer (resistivity is ˜4,000 ohm-cm), and the display in FIG. 8c a higher resistance PANI(ES) polyblend layer (resistivity is ˜50,000 ohm-cm).

### DESCRIPTION OF THE PREFERRED EMBODIMENTS

While the formulation of the invention is useful in non-pixelated as well as pixelated electronic devices, the advantages are especially applicable in pixelated devices, such as, for example an electroluminescent display.

### Device Configuration

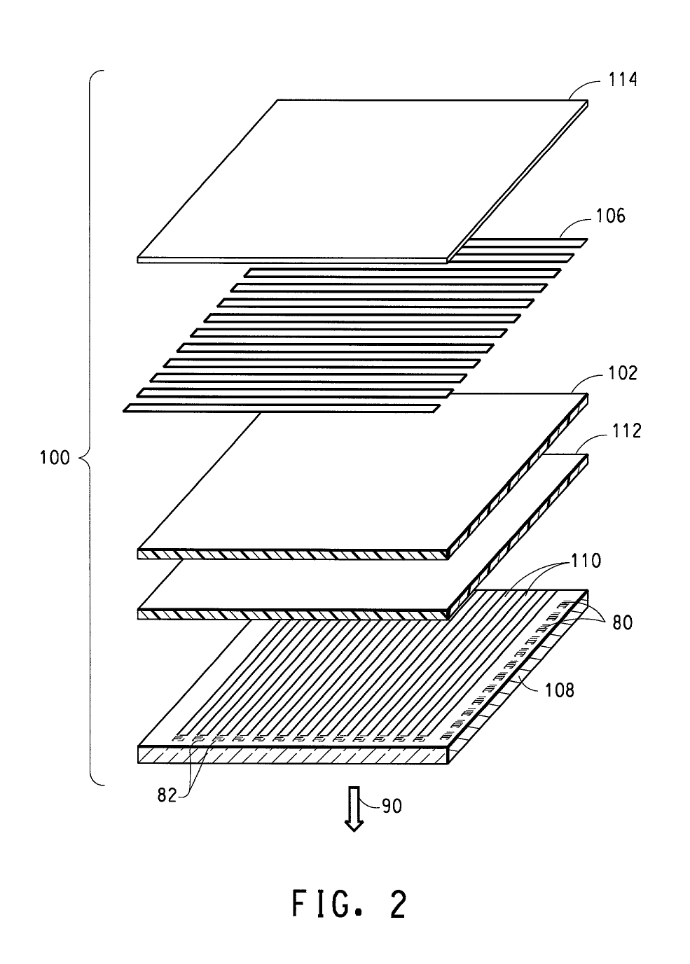

As shown in FIG. 2, each individual pixel of an organice electronic device 100 includes an electron injecting (cathode) contact 106 made from a relatively low work function metal (for example, Ca, Ba or alloys comprising Ca or Ba) as one electrode on the front of a photoactive organic material 102 deposited on a substrate 108 which has been partially coated with a layer of transparent conducting material 110 with higher work function (high ionization potential) to serve as the second (transparent) electron-withdrawing (anode) electrode; i.e. a configuration that is well known for polymer LEDs (D. Braun and A. J. Heeger, Appl. Phys. Lett. 58, 1982 (1991). In accord with this invention, a layer 112 containing at least high resistivity layer of conductivity polymer such as PANI(ES) is interposed between the luminescent polymer layer 102 and the high work function anode 110. Cathode 106 is electrically connected to contact pads 80, and anode 110 is electrically connected to contact pads 82. The layers 102, 106, 108, 110, and 112 are then isolated from the environment by a hermetic seal layer 114. Upon application of electricity via contact pads 80, 82, which pads are outside of the hermetic seal 70, light is emitted from the device in the direction shown by arrow 90.

The remainder of this description of preferred embodiments is organized according to these various components. More specifically it contains the following sections:

The Photoactive Layer (102)

The Anode (110)

The High Resistivity Layer (112)

The Cathode (106)

The Substrate (108)

Contact Pads (80, 90)

Other Optional Layers

Fabrication Techniques

Examples

The Photoactive Layer (102)

Depending upon the application of the electronic device 100, the photophotoactive layer 102 can be a light-emitting layer that is activated by an applied voltage (such as in a light-emitting diode or light-emitting electrochemical cell), a layer of material that responds to radiant energy and generates a signal with or without an applied bias voltage (such as in a photodetector). Examples of photodetectors include photoconductive cells, photoresistors, photoswitches, phototransistors, and phototubes, and photovoltaic cells, as these terms are describe in Markus, John, Electronics and Nucleonics Dictionary, 470 and 476 (McGraw-Hill, Inc. 1966).

Where the electronic device 100 is a light-emitting device, the photoactive layer 102 will emit light when sufficient bias voltage is applied to the electrical contact layers. Suitable active light-emitting materials include organic molecular materials such as anthracene, butadienes, coumarin derivatives, acridine, and stilbene derivatives, see, for example, Tang, U.S. Pat. No. 4,356,429, Van Slyke et al., U.S. Pat. No. 4,539,507, the relevant portions of which are incorporated herein by reference. Alternatively, such materials can be polymeric materials such as those described in Friend et al. (U.S. Pat. No. 5,247,190), Heeger et al. (U.S. Pat. No. 5,408,109), Nakano et al. (U.S. Pat. No. 5,317,169), the relevant portions of which are incorporated herein by reference. The light-emitting materials may be dispersed in a matrix of another material, with and without additives, but preferably form a layer alone. In preferred embodiments, the electroluminescent polymer comprises at least one conjugated polymer or a co-polymer which contains segments of π-conjugated moieties. Conjugated polymers are well known in the art (see, e.g., Conjugated Polymers, J. -L. Bredas and R. Silbey edt., Kluwer Academic Press, Dordrecht, 1991). Representative classes of materials include, but are not limited to the following:

(i) poly(p-phenylene vinylene) and its derivatives substituted at various positions on the phenylene moiety;

(ii) poly(p-phenylene vinylene) and its derivatives substituted at various positions on the vinylene moiety;

(iii) poly(arylene vinylene), where the arylene may be such moieties as naphthalene, anthracene, furylene, thienylene, oxadiazole, and the like, or one of the moieties with functionalized substituents at various positions;

(iv) derivatives of poly(arylene vinylene), where the arylene may be as in (iii) above, substituted at various positions on the arylene moiety;

(v) derivatives of poly(arylene vinylene), where the arylene may be as in (iii) above, substituted at various positions on the vinylene moiety;

(vi) co-polymers of arylene vinylene oligomers with non-conjugated oligomers, and derivatives of such polymers substituted at various positions on the arylene moieties, derivatives of such polymers substituted at various positions on the vinylene moieties, and derivatives of such polymers substituted at various positions on the arylene and the vinylene moieties;

(vii) poly(p-phenylene) and its derivatives substituted at various positions on the phenylene moiety, including ladder polymer derivatives such as poly(9,9-dialkyl fluorene) and the like;

(viii) poly(arylenes) and their derivatives substituted at various positions on the arylene moiety;

(ix) co-polymers of oligoarylenes with non-conjugated oligomers, and derivatives of such polymers substituted at various positions on the arylene moieties;

(x) polyquinoline and its derivatives;

(xi) co-polymers of polyquinoline with p-phenylene and moieties having solubilizing function;

(xii) rigid rod polymers such as poly(p-phenylene-2,6-benzobisthiazole), poly(p-phenylene-2,6-benzobisoxazole), poly(p-phenylene-2,6-benzimidazole), and their derivatives; and the like.

More specifically, the photoactive materials may include but are not limited to poly(phenylenevinylene), PPV, and alkoxy derivatives of PPV, such as for example, poly(2-methoxy-5-(2′-ethyl-hexyloxy)-p-phenylenevinylene) or “MEH-PPV” (U.S. Pat. No. 5,189,136). BCHA-PPV is also an attractive active material. (C. Zhang, et al, J. Electron. Mater., 22, 413 (1993)). PPPV is also suitable. (C. Zhang et al, Synth. Met., 62, 35 (1994) and references therein.) Luminescent conjugated polymer which are soluble in common organic solvents are preferred since they enable relatively simple device fabrication [A. Heeger and D. Braun, U.S. Pat. Nos. 5,408,109 and 5,869,350].

Even more preferred photoactive polymers and copolymers are the soluble PPV materials described in H. Becker et al., Adv. Mater. 12, 42 (2000) and referred to herein as C-PPV's. Blends of these and other semi-conducting polymers and copolymers which exhibit electroluminescence can be used.

Where the electronic device 100 is a photodetector, the photophotoactive layer 102 responds to radiant energy and produces a signal either with or without a biased voltage. Materials that respond to radiant energy and is capable of generating a signal with a biased voltage (such as in the case of a photoconductive cells, photoresistors, photoswitches, phototransistors, phototubes) include, for example, many conjugated polymers and electroluminescent materials. Materials that respond to radiant energy and are capable of generating a signal without a biased voltage (such as in the case of a photoconductive cell or a photovoltaic cell) include materials that chemically react to light and thereby generate a signal. Such light-sensitive chemically reactive materials include for example, many conjugated polymers and electro- and photo-luminescent materials. Specific examples include, but are not limited to, MEH-PPV (“Optocoupler made from semiconducting polymers”, G. Yu, K. Pakbaz, and A. J. Heeger, Journal of Electronic Materials, Vol. 23, pp 925-928 (1994); and MEH-PPV Composites with CN-PPV (“Efficient Photodiodes from Interpenetrating Polymer Networks”, J. J. M. Halls et al. (Cambridge group) Nature Vol. 376, pp. 498-500, 1995). The electroactive organic materials can be tailored to provide emission at various wavelengths.

In some embodiments, the polymeric photoactive material or organic molecular photoactive material is present in the photophotoactive layer 102 in admixture from 0% to 75% (w, basis overall mixture) of carrier organic material (polymeric or organic molecular). The criteria for the selection of the carrier organic material are as follows. The material should allow for the formation of mechanically coherent films, at low concentrations, and remain stable in solvents that are capable of dispersing, or dissolving the conjugated polymers for forming the film. Low concentrations of carrier materials are preferred in order to minimize processing difficulties, i.e., excessively high viscosity or the formation of gross in homogeneities; however the concentration of the carrier should be high enough to allow for formation of coherent structures. Where the carrier is a polymeric material, preferred carrier polymers are high molecular weight (M.W.>100,000) flexible chain polymers, such as polyethylene, isotactic polypropylene, polyethylene oxide, polystyrene, and the like. Under appropriate conditions, which can be readily determined by those skilled in the art, these macromolecular materials enable the formation of coherent structures from a wide variety of liquids, including water, acids, and numerous polar and non-polar organic solvents. Films or sheets manufactured using these carrier polymers have sufficient mechanical strength at polymer concentrations as low as 1%, even as low as 0.1%, by volume to enable the coating and subsequent processing as desired. Examples of such coherent structures are those comprised of poly(vinyl alcohol), poly(ethylene oxide), poly-para (phenylene terephthalate), poly-para-benzamide, etc., and other suitable polymers. On the other hand, if the blending of the final polymer cannot proceed in a polar environment, non-polar carrier structures are selected, such as those containing polyethylene, polypropylene, poly(butadiene), and the like.

Typical film thicknesses of the photoactive layers range from a few hundred Angstrom units (200 Å) to several thousand Angstrom units (10,000 Å) (1 Ångstrom unit=10⁻⁸ cm). Although the active film thicknesses are not critical, device performance can typically be improved by using thinner films. Preferred thickness are from 300 Å to 5,000 Å.

The Anode (110)

In the device of the invention one electrode is transparent to enable light emission from the device or light reception by the device. Most commonly, the anode is the transparent electrode, although the present invention can also be used in an embodiment where the cathode is the transparent electrode.

The anode 110 is preferably made of materials containing a metal, mixed metal, alloy, metal oxide or mixed-metal oxide. Suitable metals include the Group 11 metals, the metals in Groups 4, 5, and 6, and the Group 8-10 transition metals. If the anode is to be light-transmitting, mixed-metal oxides of Groups 12, 13 and 14 metals, such as indium-tin-oxide, are generally used. The IUPAC numbering system is used throughout, where the groups from the Periodic Table are numbered from left to right as 1-18 (CRC Handbook of Chemistry and Physics, 81^{st} Edition, 2000). The anode 110 may also comprise an organic material such as polyaniline as described in “Flexible light-emitting diodes made from soluble conducting polymer,” Nature vol. 357, pp 477-479 (Jun. 11, 1992).

Typical inorganic materials which serve as anodes include metals such as aluminum, silver, platinum, gold, palladium, tungsten, indium, copper, iron, nickel, zinc, lead and the like; metal oxides such as lead oxide, tin oxide, indium/tin-oxide and the like; graphite; doped inorganic semiconductors such as silicon, germanium, gallium arsenide, and the like. When metals such as aluminum, silver, platinum, gold, palladium, tungsten, indium, copper, iron, nickel, zinc, lead and the like are used, the anode layer must be sufficiently thin to be semi-transparent. Metal oxides such as indium/tin-oxide are typically at least semitransparent.

As used herein, the term “transparent” is defined to mean “capable of transmitting at least about 25%, and preferably at least about 50%, of the amount of light of a particular wavelength of interest”. Thus a material is considered “transparent” even if its ability to transmit light varies as a function of wavelength but does meet the 25% or 50% criteria at a given wavelength of interest. As is known to those working in the field of thin films, one can achieve considerable degrees of transparency with metals if the layers are thin enough, for example in the case of silver and gold below about 300 Å, and especially from about 20 Å to about 250 Å with silver having a relatively colorless (uniform) transmittance and gold tending to favor the transmission of yellow to red wavelengths.

The conductive metal-metal oxide mixtures can be transparent as well at thicknesses up to as high as 2500 Å in some cases. Preferably, the thicknesses of metal-metal oxide (or dielectric) layers is from about 25 to about 1200 Å when transparency is desired.

This layer is conductive and should be low resistance: preferably less than 300 ohms/square and more preferably less than 100 ohms/square.

The Buffer Layer 112

A high resistivity buffer layer 112 is placed between the layer of active material 102 and anode 110.

This layer should be a high resistivity layer and shall comprise conductive polyaniline (PANI) such as PANI(ES) or an equivalent conjugated conductive polymer, most commonly in a blend with one or more nonconductive host polymers. Suitable conductive polymers are usually doped polymers and may include materials such as poly(ethylenedioxythiophene) “PEDT”, polypyrolle, polythiophene and PANI, all in their conductive forms. Polyaniline is particularly useful, particularly when it is in the emeraldine salt (ES) form. Useful conductive polyanilines include the homopolymer and derivatives usually as blends with bulk polymers. Examples of PANI are those disclosed in U.S. Pat. No. 5,232,631. The preferred PANI blend materials for this layer have a bulk resistivity of greater than 10⁴ ohms-cm. More preferred PANI blends have a bulk resistivity of greater than 10⁵ ohms-cm.

When the terms “polyaniline” or PANI are used herein, they are used generically to include substituted and unsubstituted materials, as well as the other equivalent conjugated conductive polymers such as polypyrrole or polythiophene or PEDT, unless the context is clear that only the specific nonsubstituted form is intended. It is also used in a manner to include any accompanying dopants, particularly acidic materials used to render the polyaniline conductive.

In general, polyanilines are polymers and copolymers of film and fiber-forming molecular weight derived from the polymerization of unsubstituted and substituted anilines of the Formula I:

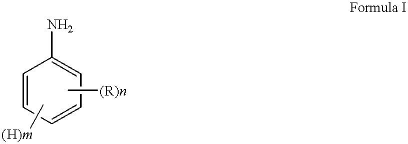

wherein

n is an integer from 0 to 4;

m is an integer from 1 to 5 with the proviso that the sum of n and m is equal to 5; and

R is independently selected so as to be the same or different at each occurrence and is selected from the group consisting of alkyl, alkenyl, alkoxy, cycloalkyl, cycloalkenyl, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, carboxylic acid, halogen, cyano, or alkyl substituted with one or more sulfonic aid, carboxylic acid, halo, nitro, cyano or epoxy moieties; or carboxylic acid, halogen, nitro, cyano, or sulfonic acid moieties; or any two R groups together may form an alkylene or alkenylene chain completing a 3, 4, 5, 6 or 7-membered aromatic or alicyclic ring, which ring may optionally include one or more divalent nitrogen, sulfur or oxygen atoms. Without intending to limit the scope of this invention, the size of the various R groups ranges from about 1 carbon (in the case of alkyl) through 2 or more carbons up through about 20 carbons with the total of n Rs being from about 1 to about 40 carbons.

Illustrative of the polyanilines useful in the practice of this invention are those of the Formula II to V:

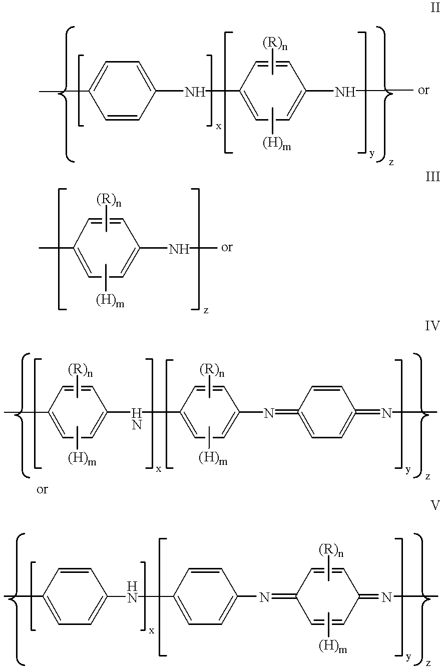

wherein:

n, m and R are as described above except that m is reduced by 1 as a hydrogen is replaced with a covalent bond in the polymerization and the sum of n plus m equals 4;

y is an integer equal to or greater than 0;

x is an integer equal to or greater than 1, with the proviso that the sum of x and y is greater than 1; and

z is an integer equal to or greater than 1.

The following listing of substituted and unsubstituted anilines are illustrative of those which can be used to prepare polyanilines useful in the practice of this invention.

| | |
|---|---|
| Aniline | 2,5-Dimethylaniline |
| o-Toluidine | 2,3-Dimethylaniline |
| m-Toluidine | 2,5-Dibutylaniline |
| o-Ethylaniline | 2,5-Dimethoxyaniline |
| m-EIthylanilin | Tetrahydronaphthylamine |
| o-Ethoxyaniline | o-Cyanoaniline |
| m-Butylaniline | 2-Thiomethylaniline |
| m-Hexylaniline | 2,5-Dichloroaniline |
| m-Octylaniline | 3-(n-Butanesulfonic acid)aniline |
| 4-Bromoaniline | |
| 2-Bromoaniline | |
| 3-Bromoaniline | 2,4-Dimethoxyaniline |
| 3-Acetamidoaniline | 4-Mercaptoaniline |
| 4-Acetamidoaniline | 4-Methylthioaniline |
| 5-Chloro-2-methoxyaniline | 3-Phenoxyaniline |
| 5-Chloro-2-ethoxyaniline | 4-Phenoxyaniline |

Illustrative of useful R groups are alkyl, such as methyl, ethyl, octyl, nonyl, tert-butyl, neopentyl, isopropyl, sec-butyl, dodecyl and the like, alkenyl such as 1-propenyl, 1-butenyl, 1-pentenyl, 1-hexenyl, 1-heptenyl, 1-octenyl and the like; alkoxy such as propoxy, butoxy, methoxy, isopropoxy, pentoxy, nonoxy, ethoxy, octoxy, and the like, cycloalkenyl such as cyclohexenyl, cyclopentenyl and the like; alkanoyl such as butanoyl, pentanoyl, octanoyl, ethanoyl, propanoyl and the like; alkylsulfinyl, alkysulfonyl, alkylthio, arylsulfonyl, arylsulfinyl, and the like, such as butylthio, neopentylthio, methylsulfinyl, benzylsulfinyl, phenylsulfinyl, propylthio, octylthio, nonylsulfonyl, octylsulfonyl, methylthio, isopropylthio, phenylsulfonyl, methylsulfonyl, nonylthio, phenylthio, ethylthio, benzylthio, phenethylthio, naphthylthio and the like; alkoxycarbonyl such as methoxycarbonyl, ethoxycarbonyl, butoxycarbonyl and the like, cycloalkyl such as cyclohexyl, cyclopentyl, cyclooctyl, cycloheptyl and the like; alkoxyalkyl such as methoxymethyl, ethoxymethyl, butoxymethyl, propoxyethyl, pentoxybutyl and the like; aryloxyalkyl and aryloxyaryl such as phenoxyphenyl, phenoxymethylene and the like; and various substituted alkyl and aryl groups such as 1-hydroxybutyl, 1-aminobutyl, 1-hydroxylpropyl, 1-hydyroxypentyl, 1-hydroxyoctyl, 1-hydroxyethyl, 2-nitroethyl, trifluoromethyl, 3,4-epoxybutyl, cyanomethyl, 3-chloropropyl, 4-nitrophenyl, 3-cyanophenyl, and the like; sulfonic acid terminated alkyl and aryl groups and carboxylic acid terminated alkyl and aryl groups such as ethylsulfonic acid, propylsulfonic acid, butylsulfonic acid, phenylsulfonic acid, and the corresponding carboxylic acids.

Also illustrative of useful R groups are divalent moieties formed from any two R groups such as moieties of the formula:

—(CH₂)—_{n*}

wherein n* is an integer from about 3 to about 7, as for example —(CH₂)—₄, —(CH₂)—₃ and —(CH₂)—₅, or such moieties which optionally include heteroatoms of oxygen and sulfur such as —CH₂SCH₂— and —CH₂—O—CH₂—. Exemplary of other useful R groups are divalent alkenylene chains including 1 to about 3 conjugated double bond unsaturation such as divalent 1,3-butadiene and like moieties.

Preferred for use in the practice of this invention are polyanilines of the above Formulas II to V in which:

n is an integer from 0 to about 2;

m is an integer from 2 to 4, with the proviso that the sum of n and m is equal to 4;

R is alkyl or alkoxy having from 1 to about 12 carbon atoms, cyano, halogen, or alkyl substituted with carboxylic acid or sulfonic acid substituents;

x is an integer equal to or greater than 1;

y is an integer equal to or greater than 0, with the proviso that the sum of x and y is greater than about 4, and

z is an integer equal to or greater than about 5.

In more preferred embodiments of this invention, the polyaniline is derived from unsubstituted aniline, i.e., where n is 0 and m is 5 (monomer) or 4 (polymer). In general, the number of monomer repeat units is at least about 50.

As described in U.S. Pat. No. 5,232,631, the polyaniline is rendered conductive by the presence of an oxidative or acidic species. Acidic species and particularly “functionalized protonic acids” are preferred in this role. A “functionalized protonic acid” is one in which the counter-ion has been functionalized preferably to be compatible with the other components of this layer. As used herein, a “protonic acid” is an acid that protonates the polyaniline to form a complex with said polyaniline.

In general, functionalized protonic acids for use in the invention are those of Formulas VI and VII:s

A—R IV

or

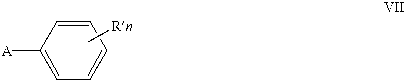

wherein:

A is sulfonic acid, selenic acid, phosphoric acid, boric acid or a carboxylic acid group; or hydrogen sulfate, hydrogen selenate, hydrogen phosphate;

n is an integer from 1 to 5;

R is alkyl, alkenyl, alkoxy, alkanoyl, alkylthio, alkylthioalkyl, having from 1 to about 20 carbon atoms; or alkylaryl, arylalkyl, alkylsulfinyl, alkoxyalkyl, alkylsulfonyl, alkoxycarbonyl, carboxylic acid, where the alkyl or alkoxy has from 0 to about 20 carbon atoms; or alkyl having from 3 to about 20 carbon atoms substituted with one or more sulfonic acid, carboxylic acid, halogen, nitro, cyano, diazo, or epoxy moieties; or a substituted or unsubstituted 3, 4, 5, 6 or 7 membered aromatic or alicyclic carbon ring, which ring may include one or more divalent heteroatoms of nitrogen, sulfur, sulfinyl, sulfonyl or oxygen such as thiophenyl, pyrolyl, furanyl, pyridinyl.

In addition to these monomeric acid forms, R can be a polymeric backbone from which depend a plurality of acid functions “A.” Examples of polymeric acids include sulfonated polystyrene, sulfonated polyethylene and the like. In these cases the polymer backbone can be selected either to enhance solubility in nonpolar substrates or be soluble in more highly polar substrates in which materials such as polymers, polyacrylic acid or poly(vinylsulfonate), or the like, can be used.

R′ is the same or different at each occurrence and is alkyl, alkenyl, alkoxy, cycloalkyl, cycloalkenyl, alkanoyl, alkylthio, aryloxy, alkylthioalkyl, alkylaryl, arylalkyl, alkylsulfinyl, alkoxyalkyl, alkylsulfonyl, aryl, arylthio, arylsulfinyl, alkoxycarbonyl, arylsulfonyl, carboxylic acid, halogen, cyano, or alkyl substituted with one or more sulfonic acid, carboxylic acid, halogen, nitro, cyano, diazo or epoxy moieties; or any two R substituents taken together are an alkylene or alkenylene group completing a 3, 4, 5, 6 or 7 membered aromatic or alicyclic carbon ring or multiples thereof, which ring or rings may include one or more divalent heteroatoms of nitrogen, sulfur, sulfinyl, sulfonyl or oxygen. R′ typically has from about 1 to about 20 carbons especially 3 to 20 and more especially from about 8 to 20 carbons.

Materials of the above Formulas VI and VII are preferred in which:

A is sulfonic acid, phosphoric acid or carboxylic acid;

n is an integer from 1 to 3;

R is alkyl, alkenyl, alkoxy, having from 6 to about 14 carbon atoms; or arylalkyl, where the alkyl or alkyl portion or alkoxy has from 4 to about 14 carbon atoms; or alkyl having from 6 to about 14 carbon atoms substituted with one or more, carboxylic acid, halogen, diazo, or epoxy moieties;

R′ is the same or different at each occurrence and is alkyl, alkoxy, alkylsulfonyl, having from 4 to 14 carbon atoms, or alkyl substituted with one or more halogen moieties again with from 4 to 14 carbons in the alkyl.

Among the particularly preferred embodiments, most preferred for use in the practice of this invention are functionalized protonic acids of the above Formulas VI and VII in which:

A is sulfonic acid;

n is the integer 1 or 2;

R is alkyl or alkoxy, having from 6 to about 14 carbon atoms; or alkyl having from 6 to about 14 carbon atoms substituted with one or more halogen moieties;

R′ is alkyl or alkoxy, having from 4 to 14, especially 12 carbon atoms, or alkyl substituted with one or more halogen, moieties.

Preferred functionalized protonic acids are organic sulfonic acids such as dodecylbenzene sulfonic acid and more preferably poly(2-acrylamido-2-methyl-1-propanesulfonic acid) (“PAAMPSA”).

The amount of functionalized protonic acid employed can vary depending on the degree of conductivity required. In general, sufficient functionalized protonic acid is added to the polyaniline-containing admixture to form a conducting material. Usually the amount of functionalized protonic acid employed is at least sufficient to give a conductive polymer (either in solution or in solid form).

The polyaniline can be conveniently used in the practice of this invention in any of its physical forms. Illustrative of useful forms are those described in Green, A. G., and Woodhead, A. E., J. Chem. Soc., 101, 1117 (1912) and Kobayashi, et al., J. Electroanl. Chem., 177, 281-91 (1984), which are hereby incorporated by reference. For unsubstituted polyaniline, useful forms include leucoemeraldine, protoemeraldine, emeraldine, nigraniline and tolu-protoemeraldine forms, with the emeraldine form being preferred.

Copending U.S. Patent Application Ser. No. 60/168,856 of Cao, Y. and Zhang, C. discloses the formation of low conductivity blends of conjugated polymers with non-conductive polymers and is incorporated herein by reference.

The particular bulk polymer or polymers added to the conjugated polymer can vary. The selection of materials can be based upon the nature of the conductive polymer, the method used to blend the polymers and the method used to deposit the layer in the device.

The materials can be blended by dispersing one polymer in the other, either as a dispersion of small particles or as a solution of one polymer in the other. The polymer are typically admixed in a fluid phase and the layer is typically laid out of a fluid phase.

We have had our best results using water-soluble or water-dispensable conjugated polymers together with water-soluble or water-dispensable bulk polymers. In this case, the blend can be formed by dissolving or dispersing the two polymers in water and casting a layer from the solution or dispersion.

Organic solvents can be used with organic-soluble or organic dispensable conjugated polymers and bulk polymers. In addition, blends can be formed using melts of the two polymers or by using a liquid prepolymer or monomer form of the bulk polymer which is subsequently polymerized or cured into the desired final material.

In those presently preferred cases where the PANI is water-soluble or water dispersable and it is desired to cast the PANI layer from an aqueous solution, the bulk polymer should be water soluble or water dispersible. In such cases, it is selected from, for example polyacrylamides (PAM), poly(acrylic acid) (PAA) poly(vinyl pyrrolidone) (PVPd), acrylamide copolymers, cellulose derivatives, carboxyvinyl polymer, poly(ethylene glycols), poly(ethylene oxide) (PEO), poly(vinyl alcohol) (PVA), poly(vinyl methyl ether), polyamines, polyimines, polyvinylpyridines, polysaccharides, and polyurethane dispersions.

In the case where it is desired to cast the layer from a non-aqueous solution or dispersion the bulk polymer may be selected from, for example liquefiable polyethylenes, isotactic polypropylene, polystyrene, poly(vinylalcohol), poly(ethylvinylacetate), polybutadienes, polyisoprenes, ethylenevinylene-copolymers, ethylene-propylene copolymers, poly(ethyleneterephthalate), poly(butyleneterephthalate) and nylons such as nylon 12, nylon 8, nylon 6, nylon 6.6 and the like, polyester materials, polyamides such as polyacrylamides and the like.

In those cases where one polymer is being dispersed in the other, the common solubility of the various polymers may not be required.

The relative proportions of the polyaniline and bulk polymer or prepolymer can vary. For each part of polyaniline there can be from 0 to as much as 20 parts by weight of bulk polymer or prepolymer with 0.5 to 10 and especially 1 to 4 parts of bulk material being present for each part of PANI.

Solvents for the materials used to cast this layer are selected to compliment the properties of the polymers.

In the preferred systems, the PANI and bulk polymer are both water-soluble or water-dispersible and the solvent system is an aqueous solvent system such as water or a mixture of water with one or more polar organic materials such as lower oxyhydrocarbons for example lower alcohols, ketones and esters.

These materials include, without limitation, water mixed with methanol, ethanol, isopropanol, acetone methyl ethyl ketone and the like.

If desired, but generally not preferred, a solvent system of polar organic liquids could be used.

In the case of conducting polymers such as PANI and bulk polymers which are not water-soluble or water-dispersible, nonpolar solvents are most commonly used.

Illustrative of useful common nonpolar solvents are the following materials: substituted or unsubstituted aromatic hydrocarbons such as benzene, toluene, p-xylene, m-xylene, naphthalene, ethylbenzene, styrene, aniline and the like; higher alkanes such as pentane, hexane, heptane, octane, nonane, decane and the like; cyclic alkanes such as decahydronaphthalene; halogenated alkanes such as chloroform, bromoform, dichloromethane and the like; halogenated aromatic hydrocarbons such as chlorobenzene, o-dichlorobenzene, m-dichlorobenzene, p-dichlorobenzene and the like; higher alcohols such as 2-butanol, 1-butanol, hexanol, pentanol, decanol, 2-methyl-1-propanol and the like; higher ketones such as hexanone, butanone, pentanone and the like; heterocyclics such as morpholine; perfluorinated hydrocarbons such as perfluorodecaline, perfluorobenzene and the like.

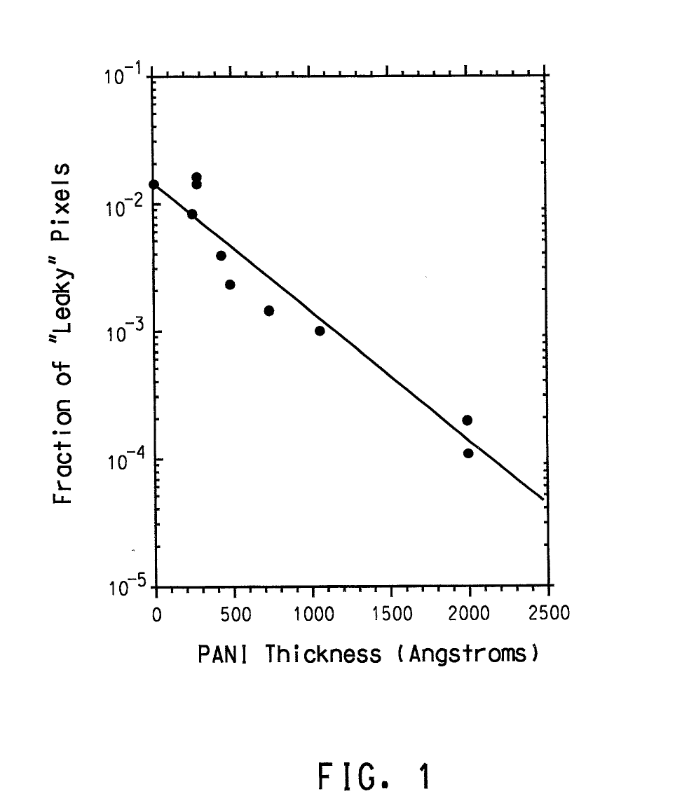

The thickness of the conjugated polymer layer will be chosen with the properties of the diode in mind. In those situations where the composite anode is to be transparent, it is generally preferable to have the layer of PANI as thin as practically possible bearing in mind the failure problem noted in FIG. 1. Typical thicknesses range from about 100 Å to about 5000 Å. When transparency is desired, thicknesses of from about 100 Å to about 3000 Å are preferred and especially about 2000 Å.

With a film thickness of 200 nm or greater, the electrical resistivity of the PANI(ES) blend layer should be greater than or equal to 10⁴ ohm-cm to avoid cross talk and inter-pixel current leakage. Values in excess of 10⁵ ohm-cm are preferred. Even at 10⁵ ohm-cm, there is some residual current leakage and consequently some reduction in device efficiency. Thus, values of approximately 10⁵ to 10⁸ ohm-cm are even more preferred. Values greater than 10⁹ ohm-cm will lead to a significant voltage drop across the injection/buffer layer and therefore should be avoided.

The Cathode (106)

Suitable materials for use as cathode materials are any metal or nonmetal having a lower work function than the first electrical contact layer (in this case, an anode). Materials for the cathode layer 106 (in this case the second electrical contact) can be selected from alkali metals of Group 1 (e.g., Li, Cs), the Group 2 (alkaline earth) metals—commonly calcium, barium, strontium, the Group 12 metals, the rare earths—commonly ytterbium, the lanthanides, and the actinides. Materials such as aluminum, indium and copper, silver, combinations thereof and combinations with calcium and/or barium, Li, magnesium, LiF can be used.

Alloys of low work function metals, such as for example alloys of magnesium in silver and alloys of lithium in aluminum, are also useful. The thickness of the electron-injecting cathode layer ranges from less than 15 Å to as much as 5,000 Å. This cathode layer 106 can be patterned to give a pixellated array or it can be continuous and overlaid with a layer of bulk conductor such as silver, copper or preferably aluminum which is, itself, patterned.

The cathode layer may additionally include a second layer of a second metal added to give mechanical strength and durability.

The Substrate (108)

In most embodiments, the diodes are prepared on a substrate. Typically the substrate should be nonconducting. In those embodiments in which light passes through it, it is transparent. It can be a rigid material such as a rigid plastic including rigid acrylates, carbonates, and the like, rigid inorganic oxides such as glass, quartz, sapphire, and the like. It can also be a flexible transparent organic polymer such as polyester—for example poly(ethyleneterephthalate), flexible polycarbonate, poly (methyl methacrylate), poly(styrene) and the like.

The thickness of this substrate is not critical.

Contact Pads (80, 82)

Any contact pads 80, 82 useful to connect the electrode of the device 100 to the power source (not shown) can be used, including, for example, conductive metals such as gold (Au), silver (Ag), nickel (Ni), copper (Cu) or aluminum (Al).

Preferably, contact pads 80, 82 have a height (not shown) projected beyond the thickness of the high work function electrode lines 110 below the total thickness of layer.

Preferably, the dimensions of layers 102, 110, and 112 are such that contacts pads 80 are positioned on a section of the substrate 108 not covered by layers 102,112 and 114. In addition, the dimensions of layer 106, 102, 110, and 112 are such that the entire length and width electrode lines 106 and electrode lines 110 have at least one layer 102, 112 intervening between the electrodes 106, 110, while electrical connection can be made between electrode 106 and contact pads 80.

Other Optional Layers (Not Shown)

An optional layer including an electron injection/transport material may be provided between the photoactive layer 102 and the cathode 106. This optional layer can function both to facilitate electron injection/transport, and also serve as a buffer layer or confinement layer to prevent quenching reactions at layer interfaces. Preferably, this layer promotes electron mobility and reduces quenching reactions. Examples of electron transport materials for optional layer include metal chelated oxinoid compounds, such as tris(8-hydroxyquinolato)aluminum (Alq₃); phenanthroline-based compounds, such as 2,9-dimethyl-4,7-diphenyl-1,10-phenanthroline (DDPA) or 4,7-diphenyl-1,10-phenanthroline (DPA), and azole compounds such as 2-(4-biphenylyl)-5-(4-t-butylphenyl)-1,3,4-oxadiazole (PBD) and 3-(4-biphenylyl)-4-phenyl-5-(4-t-butylphenyl)-1,2,4-triazole (TAZ), polymers containing DDPA, DPA, PBD, and TAZ moiety and polymer blends thereof, polymer blends containing containing DDPA, DPA, PBD, and TAZ.

It is known to have other layers in organic electronic devices. For example, there can be a layer (not shown) between the buffer layer 112 and the photphotoactive layer 102 to facilitate positive charge transport and/or band-gap matching of the layers, or to function as a protective layer, or to improve the interfacial property. Similarly, there can be additional layers (not shown) between the photoactive layer 102 and the cathode layer 106 to facilitate negative charge transport and/or band-gap matching between the layers, or to function as a protective layer. Layers that are known in the art can be used. In addition, any of the above-described layers can be made of two or more layers. Alternatively, some or all of anode layer 110, the buffer layer 112 the photophotoactive layer 102, and cathode layer 106, may be surface treated to increase charge carrier transport efficiency. The choice of materials for each of the component layers is preferably determined by balancing the goals of providing a device with high device efficiency.

Fabrication Techniques

The various elements of the devices of the present invention may be fabricated by any of the techniques well known in the art, such as solution casting, screen printing, web coating, ink jet printing, sputtering, evaporation, precursor polymer processing, melt-processing, and the like, or any combination thereof. In the most common approach, the diodes are built up by sequential deposit of layers upon a substrate. In a representative preparation, the inorganic contact 110 portion of the composite electrode is laid down first. This layer is commonly deposited by vacuum sputtering (RF or Magnetron), electron beam evaporation, thermal vapor deposition, chemical deposition or the like methods commonly used to form inorganic layers.

Next, the buffer layer 112 is laid down. This layer is usually most conveniently deposited as a layer from solution by spin casting or like technique. In those preferred cases where the layer is formed from water-soluble or water-dispersible material water is generally used as the spin-casting medium. In cases where a non-aqueous solvent is called for are used such as toluene, xylenes, styrene, aniline, decahydronaphthalene, chloroform, dichloromethane, chlorobenzenes and morpholine.

Next, the photoactive layer 102 of conjugated polymer is deposited. The conjugated polymer can be deposited or cast directly from solution. The solvent employed is one which will dissolve the polymer and not interfere with its subsequent deposition. Depending upon the active polymer used the solvent can be non-aqueous or aqueous.

Typically, non-aqueous solvents include halohydrocarbons such as methylene chloride, chloroform, and carbon tetrachloride, aromatic hydrocarbons such as xylene, benzene, toluene, other hydrocarbons such as decaline, and the like. Mixed solvents can be used, as well. Polar solvents such as water, acetone, acids and the like may be suitable. These are merely a representative exemplification and the solvent can be selected broadly from materials meeting the criteria set forth above.

When depositing various polymers on a substrate, the solution can be relatively dilute, such as from 0.1 to 20% w in concentration, especially 0.2 to 5% w. Film thicknesses of 500-4000 and especially 1000-2000 Å are typically used.

Finally the low work function electron-injecting contact is added. This contact is typically vacuum evaporated onto the top surface of the active polymer layer.

These steps can be altered and even reversed if an “upside down” diode is desired, so that the cathode, rather than the anode, is the transparent electrode.

It will also be appreciated that the structures just described and their fabrication can be altered to include other layers for physical strength and protection, to alter the color of the light emission or sensitivity of the diodes or the like.

The invention is based on the development of formulations of conductive conjugated polymers such as the emraldine salt (ES) of polyaniline, PANI(ES), which leads to high resistivity films for use in high efficiency pixelated polymer electronic devices such as emissive displays and a method has been developed for casting transparent thin films of the high resistivity conductive polymers onto pre-patterned ITO substrates. In addition, a method has been developed for depositing a thin transparent film of high resisitivity materials such as PANI(ES) from an aqueous dispersion onto a either pre-patterned ITO-on-glass substrates or ITO-on-plastic substrates. By using the high resistivity layer described in this invention, longer operating life is enabled in high information content displays without the need for registered patterning of the high resistivity layer.

The invention will be further described by the following Examples which are presented to illustrate the invention but not to limit its scope.

Unless otherwise specified all percentages are percentages by weight.

### EXAMPLES

### Example 1

PANI-PAAMPSA was prepared using a procedure similar to that described in the reference Y. Cao, et al, Polymer, 30(1989) 2305, more specifically, as described below. HCl in this reference was replaced by poly(2-acrylamido-2-methyl-1-propanesulfonic acid (PAAMPSA) (available from Aldrich, Milwaukee, Wis. 53201).

The emeraldine salt (ES) form was verified by the typical green color. First, 30.5 g (0.022 mole) of 15% PAAMPSA in water (Aldrich) was diluted to 2.3% by adding 170 ml water. While stirring, 2.2 g (0.022M) aniline was added into the PAAMPSA solution. Then, 2.01 g (0.0088M) of ammonium persulfate in 10 ml water was added slowly into the aniline/PAAMPSA solution under vigorous stirring. The reaction mixture was stirred for 24 hours at room temperature. To precipitate the product, PANI-PAAMPSA, 1000 ml of acetone was added into reaction mixture. Most of acetone/water was decanted and then the PANI-PAAMPSA precipitate was filtered. The resulting gum-like product was washed several times by acetone and dried at 40° C. under dynamic vacuum for 24 hours.

This Example demonstrates the direct synthesis of PANI-PAAMPSA.

### Example 2

One gram (1.0 g) of the PANI-PAAMPSA powder as prepared in Example 1 was mixed with 100 g of deionized water in a plastic bottle. The mixture was rotated at room temperature for 48 hours. The solutions/dispersions were then filtered through 0.45 μm polypropylene filters. Different concentrations of PANI-PAAMPSA in water are routinely prepared by changing the quantity of PANI-PAAMPSA mixed into the water.

This Example demonstrates that PANI-PAAMPSA can be dissolved/dispersed in water and subsequently filtered through a 0.45 μm filter.

### Example 3

A PANI-PAAMPSA film was drop-casted from 1% w/w) solution/dispersion in water. The film thickness was measured to be 650 nm by a surface profilometer (Alpha-Step 500) (available from KLA-Tencor, San Jose, Calif. 95134). Using standard X-ray equipment, a wide-angle diffraction diagram (WAXD) was taken on the PANI-PAAMPSA film. The diffraction pattern showed no characteristic diffraction peaks; the data indicated that the film was amorphous.

This Example demonstrates that the PANI-PAAMPSA film cast from water is amorphous (crystallinity less than 10%).

### Example 4

Four grams (4.0 g) of polyacrylamide (PAM) (M.W. 5,000,000-6,000,000, available from Polysciences (Warrinton, Pa. 18976) was mixed with 400 ml deionized water in a plastic bottle. The mixture was rotated at room temperature for at least 48 hours. The solution/dispersion was then filtered through 1 μm polypropylene filters. Different concentrations of PAM are routinely prepared by changing the quantity of PAM dissolved.

This Example demonstrates that PAM can be dissolved/dispersed in water and subsequently filtered through a 1 μm filter.

### Example 5

Ten grams (10 g) of the PANI-PAAMPSA solution as prepared in Example 2 was mixed with 20 g of 1% (w/w) PAM solution as prepared in Example 4 (mixed at room temperature for 24 hours). The solution was then filtered through 0.45 μm polypropylene filters. The PANI-PAAMPSA to PAM ratio was 1:2 in the blend solution. Different blend ratios of the PANI-PAAMPSA/PAM solutions were prepared by changing the concentrations of PANI-PAAMPSA and PAM in the starting solutions including the following: PANI-PAAMPSA/PAM (w/w) at 2/1, and 1/1.

This Example demonstrates that PANI-PAAMPSA/PAM blends can be prepared with a range of PAM concentrations, that these blends can be dissolved/dispersed in water and that they can be filtered through a 0.45 μm.

### Example 6

Example 5 was repeated, but PAAMPSA was used instead of PAM. The blend ratio of PANI-PAAMPSA/PAAMPSA (w/w) was, respectively, 1/0.1, 1/0.3, 1/0.5, 1/1 and 1/2.

This Example demonstrates that PANI-PAAMPSA/PAAMPSA blends can be prepared with a range of PAAMPSA concentrations, that these blends can be dissolved/dispersed in water and that they can be filtered through a 0.45 μm filter.

### Example 7

Example 5 was repeated, but PEO was used instead of PAM. The blend ratio of PANI-PAAMPSA/PEO (w/w) was 1/1.

### Example 8

Glass substrates were prepared with patterned ITO electrodes. Using the blend solutions as prepared in Examples 5, 6 and 7, polyaniline blend layers were spin-cast on top of the patterned substrates and thereafter, baked at 90° C. in a vacuum oven for 0.5 hour. The resistance between ITO electrodes was measured using a high resistance Keithley 487 Picoammeter, from Keithley Instruments Inc., (Cleveland, Ohio 44139). Table 1 shows the conductivity of PANI(ES)-blend films with different blend compositions. As can be seen from Table, the conductivity can be controlled over a wide range.

This Example demonstrates that the PANI-PAAMPSA blends can be prepared with bulk conductivities less than 10⁻⁴ S/cm, and even less than 10⁻⁵ S/cm; i.e. sufficiently low that interpixel current leakage can be limited without need for patterning the PANI-PAAMPSA blend film.

TABLE 1
Surface resistivity and bulk conductivity of PANI-PAAMPSA blends

| | host polymer | | | Surface | | Electrical |
|---|---|---|---|---|---|---|
| | (B) | Thickness | A/B ratio* | Resistance | Conductivity | Resistivity |
| Blend | (if present) | (Å) | (w/w) | (ohm/sq) | (S/cm) | (ohm-cm)** |
| 100 | none | 350 | | 1.2 × 10⁸ | 2.3 × 10⁻³ | 4.3 × 10² |
| 101 | none | 200 | | 2.2 × 10⁸ | 2.2 × 10⁻³ | 4.5 × 10² |
| 102 | PAM | 300 | 2/1 | 2.3 × 10⁹ | 1.5 × 10⁻⁴ | 6.7 × 10³ |
| 103 | PAM | 230 | 2/1 | 5.3 × 10⁹ | 8.2 × 10⁻⁵ | 1.2 × 10⁴ |
| 104 | PAM | 510 | 1/1 | 8.2 × 10⁹ | 2.3 × 10⁻⁵ | 4.3 × 10⁴ |
| 105 | PAM | 264 | 1/1 | ^{2.0 × 10}¹⁰ | 1.9 × 10⁻⁵ | 5.3 × 10⁴ |
| 106 | PAM | 220 | 1/1 | ^{2.2 × 10}¹⁰ | 2.1 × 10⁻⁵ | 4.8 × 10⁴ |
| 107 | PAM | 285 | 1/2 | ^{1.4 × 10}¹¹ | 2.5 × 10⁻⁶ | 4 × 10⁵ |
| 108 | PAAMPSA | 260 | 1/0.1 | 2.4 × 10⁹ | 1.6 × 10⁻⁴ | 6.3 × 10³ |
| 109 | PAAMPSA | 350 | 1/0.3 | 9.2 × 10⁹ | 4.6 × 10⁻⁴ | 2.2 × 10³ |
| 110 | PAAMPSA | 230 | 1/0.5 | 4.5 × 10⁸ | 9.5 × 10⁻⁴ | 1.1 × 10³ |
| 111 | PAAMPSA | 630 | 1/0.5 | 3.7 × 10⁸ | 4.3 × 10⁻⁴ | 2.3 × 10³ |
| 112 | PAAMPSA | 920 | 1/0.5 | 6.8 × 10⁷ | 1.6 × 10⁻⁴ | 6.3 × 10³ |
| 113 | PAAMPSA | 950 | 1/1 | 2.8 × 10⁸ | 3.8 × 10⁻⁴ | 2.6 × 10³ |
| 114 | PAAMPSA | 1280 | 1/1 | 6.7 × 10⁷ | 1.2 × 10⁻³ | 8.3 × 10² |
| 115 | PAAMPSA | 1740 | 1/2 | 2.5 × 10⁸ | 2.3 × 10⁻⁴ | 4.3 × 10³ |
| 116 | PAAMPSA | 3060 | 1/2 | 8.4 × 10⁷ | 3.9 × 10⁻⁴ | 2.6 × 10³ |
| 117 | PEO | 250 | 1/1 | 3.0 × 10⁹ | 1.3 × 10⁻⁴ | 7.7 × 10³ |

*A being PANI-PAAMPSA
**Electrical Resistance (i.e., inverse of conductivity)

### Example 9

20 g of a PANI-PAAMPSA solution as prepared in Example 2 was mixed (at room temperature for 12 days) with 10 g of 1 wt % PAM solution as prepared in Example 4 and 2.0 g of 15% PAAMPSA solution (available from Aldrich) The solution was then filtered through 0.45 μm polypropylene filters. The content of PANI-PAAMPSA in the blend solution was 33wt % Different blend ratios of the PANI-PAAMPSA:PAAMPSA:PAM blend solutions are prepared by changing the concentrations in the starting solutions.

### Example 10

Example 9 was repeated; the content of PANI-PAAMPSA is kept at 33wt %, but the ratio of host polymers PAAMPSA/PAM (w/w) was changed to 2/0, 0.5/1, 1/1 and 0/2, respectively.

### Example 11

30 g of a solution as prepared in Example 2 was mixed with 15 g of deionized water and 0.6 g of PAM (M.W. 5,000,000-6,000,000, available from Polysciences) under stirring at room temperature for 4-5 days. The ratio of PANI-PAAMPSA to PAM in the blend solution was 1/2. Blend solutions were also prepared in which the content of PANI-PAAMPSA was 0, 10, 25 and 40%, respectively.

### Example 12

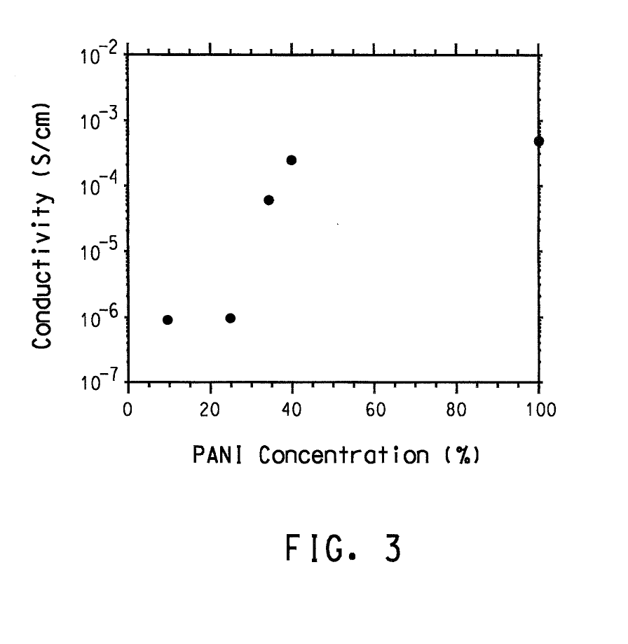

The resistance measurements of Example 8 were repeated, but the PANI(ES) layer was spin-cast from the blend solutions prepared in Examples 11. FIG. 3 shows the conductivity of PANI(ES)-blend films with different blend compositions. As can be seen from the data, the conductivity can be controlled in wide range to meet display requirements. Conductivity values less than 10⁻⁵ S/cm (electrical resistivity of greater than 10⁵ ohm-cm). can be obtained. With higher concentrations of PAM in the blend, the conductivity dropped below 10⁻⁶ S/cm (electrical resistivity of greater than 10⁶ ohm-cm).

This Example demonstrates that PANI(ES)-blend films can be prepared with conducitivities less than 10⁻⁵ S/cm and even less than 10⁻⁶ S/cm.

### Example 13

The resistance measurements of Example 8 were repeated, but the PANI(ES) layer was spin-cast from the blend solutions as prepared in Examples 9 and 10. Table 2 shows the conductivity of polyblend films with different blend compositions; the conductivity can be controlled over a wide range of values.

This Example demonstrates that the PANI-PAAMPSA blends using PAAMPSA/PAM as host polymers can be prepared with bulk conductivities less than 10⁻⁵ S/cm, even less than 10⁻⁶ S/cm and for specific formulations less than 10⁻⁷ S/cm. The conductivities of the PANI(ES) blends are sufficiently low that interpixel current leakage can be limited without need for patterning the blend film.

TABLE 2
Bulk ans surface resistance for PANI(ES) blends
with different compositions and thickness

| Ratio of* | Thick | | | Conduc- | Resis- |
|---|---|---|---|---|---|
| host polymers | ness | | | tivity | tivity |
| PAAMPS/PAM | (Å) | R (ohm)** | ohm/sq | (S/cm) | (ohm-cm) |
| 1.5/0.5 | 2100 | 9.8 × 10⁶ | 5.2 × 10⁸ | 9.0 × 10⁻⁵ | 1.1 × 10⁴ |
| | 1000 | 1.0 × 10⁸ | 5.3 × 10⁹ | 1.9 × 10⁻⁵ | 5.3 × 10⁴ |
| 2/0 | 2080 | 1.6 × 10⁷ | 8.5 × 10⁸ | 5.6 × 10⁻⁵ | 1.8 × 10⁴ |
| | 1300 | 3.9 × 10⁷ | 2.1 × 10⁹ | 3.7 × 10⁻⁵ | 2.7 × 10⁴ |
| 0.5/1 | 1850 | 1.2 × 10⁹ | 6.4 × 10¹⁰ | 9.3 × 10⁻⁷ | 1.1 × 10⁶ |
| | 1000 | 6.8 × 10⁹ | 3.6 × 10¹¹ | 2.8 × 10⁻⁷ | 3.6 × 10⁶ |
| 1/1 | 1620 | 1.1 × 10⁹ | 5.9 × 10¹⁰ | 1.0 × 10⁻⁶ | 1.6 × 10⁶ |
| | 1100 | ^{2.6 × 10}¹⁰ | 1.4 × 10¹² | 6.5 × 10⁻⁸ | 1.5 × 10⁷ |
| 0/2 | 1200 | ^{2 × 10}¹⁰ | 1.0 × 10¹² | 8.3 × 10⁻⁸ | 1.2 × 10⁷ |
| | 750 | ^{3.4 × 10}¹¹ | 1.8 × 10¹³ | 7.4 × 10⁻⁹ | 1.4 × 10⁸ |

*Ratio of polyaniline to total host polymer is 1/2 (w/w)
**Resistance between two adjacent ITO lines in 10 × 10 configuration

### Example 14

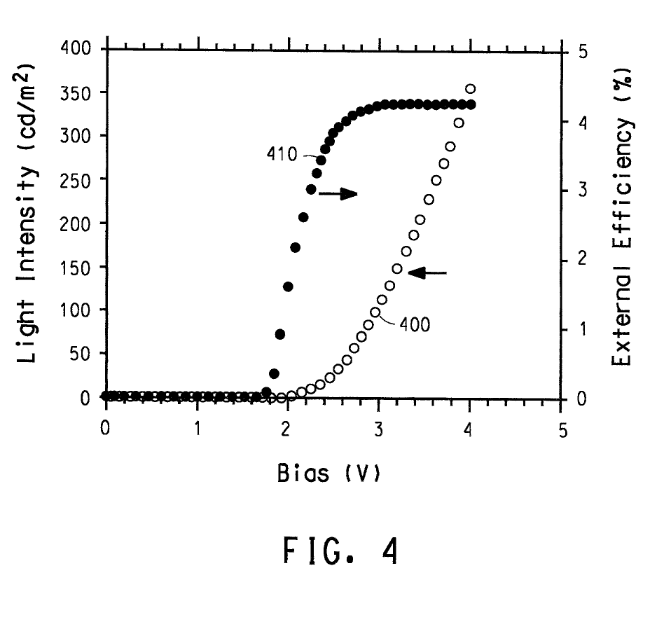

Light emitting diodes were fabricated using poly(2-(3,7dimethyloctyloxy)-5-methoxy-1,4-phenylenevinylene) (DMO-PPV) as the active semiconducting, luminescent polymer; the thickness of the DMO-PPV films were 500-1000 Å. Indium/tin oxide was used as the first layer of the bilayer anode. PANI-PAAMPSA (of Example 2) was spin-coated from 1% solution/dispersion in water onto ITO with thicknesses ranging from 100 to 800 Å, and thereafter, baked at 90° C. in vacuum oven for 0.5 hour. The device architecture was ITO/PANI(ES)-PAAMPSA/DMO-PPV/metal. Devices were fabricated using both ITO on glass as the substrate (Applied ITO/glass) and using ITO on plastic, polyethylene terephthalate, PET, as the substrate (Courtauld's ITO/PEI); in both cases, ITO/PANI-PAAMPSA bilayer was the anode and the hole-injecting contact. Devices were made with a layer of Ba as the cathode. The metal cathode film was fabricated on top of the DMO-PPV layer using vacuum vapor deposition at pressures below 1×10⁻⁶ Torr yielding an acting layer with area of 3 cm². The deposition was monitored with a STM-100 thickness/rate meter, available from Sycon Instruments, Inc., (East Syracuse, N.Y. 13057) 2,000 Å to 5,000 Å of aluminum was deposited on top of the calcium layer. For each of the devices, the current vs. voltage curve, the light vs. voltage curve, and the quantum efficiency were measured. FIG. 4 shows the light output (curve 400) and external quantum efficiency (curve 410) of ITO/PANI(ES)-PAAMPSA/DMO-PPV/Ba device. The external efficiency of the device with bilayer PANI(ES)-PAAPMSA/ITO anode is significantly higher than device with ITO anode.

This Example demonstrates that high performance polymer LEDs can be fabricated using PANI-PAAMPSA as the second layer of the bilayer anode.

### Example 15

The resistance measurements of Example 8 were repeated using commercially available poly(ethylenedioxythiophene), PEDT, polyblend solutions available from Bayer AG (Pittsburgh, Pa. 15205). Table 3 shows that the PANI(ES) blends prepared by this invention (see EXAMPLE 9) yield a layer with much lower conductivity than that obtained from PEDT. This Example demonstrates that the conductivity of PEDT is too high to be used in passively addressed pixelated displays; the inter-pixel leakage current will lead to cross-talk and to reduced efficiency.

TABLE 3
Thickness and conductivity of new PEDT-PSS
in comparison with PANI(ES) blend

| | Spin speed | Thickness | R* | Rs | Conductivity | Resistivity |
|---|---|---|---|---|---|---|
| Type | (RPM) | (Å) | (Mohm) | (Mohm/sq) | (S/cm) | (ohm-cm) |
| PEDT-PSS | 600 | 2800 | 0.22 | 11.7 | 3.0 × 10⁻³ | 3.3 × 10² |
| | 800 | 2500 | 0.31 | 16.5 | 2.4 × 10⁻³ | 4.2 × 10² |
| | 1000 | 2000 | 0.33 | 17.0 | 2.9 × 10⁻³ | 3.4 × 10² |
| | 1400 | 1700 | 0.38 | 19.4 | 3.0 × 10⁻³ | 3.3 × 10² |
| | 2000 | 1330 | 0.57 | 30.4 | 2.5 × 10⁻³ | 4.0 × 10² |
| | 4000 | 1000 | 0.77 | 41.0 | 2.4 × 10⁻³ | 4.2 × 10² |
| PEDT-TSS | 600 | 1000 | 0.16 | 8.5 | 1.2 × 10⁻² | 8.3 × 10¹ |
| | 1000 | 760 | 0.19 | 10.1 | 1.3 × 10⁻² | 7.7 × 10¹ |
| PANI(ES) | 1000 | 2100 | 9.8 | 522 | 9.0 × 10⁻⁵ | 1.1 × 10⁴ |
| blend | | | | | | |
| | 2000 | 1500 | 29.0 | 1550 | 4.3 × 10⁻⁵ | 2.3 × 10⁴ |
| | 3000 | 1200 | 84.0 | 4480 | 1.9 × 10⁻⁵ | 5.3 × 10⁴ |
| | 4000 | 1000 | 100.0 | 5300 | 1.9 × 10⁻⁵ | 5.3 × 10⁴ |
| R*: resistance between two adjacent ITO lines in 10 × 10 configuration (in mega | | | | | | |
| # ohms); | | | | | | |

Rs: surface resistance (in mega ohm/sq)

### Example 16

Example 5 was repeated, but the host polymer was, respectively, poly(acrylic acid), PAM-carboxy, polyvinylpyrrolidone and polystyrene (aqueous emulsion) instead of PAM. PANI-PAAMPSA/host polymersolution/dispersion was prepared as indicated in Example 5.

### Example 17

The device measurements summarized in Example 14 were repeated, but the PANI(ES)-blend layer was spin-cast from the blend solutions as prepared in Examples 5 and 16. Table 4 shows the device performance of LEDs fabricated from polyblend films with different host polymers.

This Example demonstrates that the use of PANI-PAAMPSA blends can be used to fabricate polymer LEDs with significantly higher efficiency; this higher efficiency is obtained because inter-pixel current leakage has been significantly reduced by using the high resistance PANI(ES)-blend as the hole injection layer.

TABLE 4
Performance of devices fabricated with different PANI(ES) blends #

| | Performance at 8.3 mA/cm²* | | | |
|---|---|---|---|---|
| Host polymer | V | QE (%) | cd/A | Lm/W |
| PAM (300Å) | 4.9 | 3.5 | 6.3 | 4.1 |
| PAM (2000Å)** | 4.3 | 3.1 | 4.5 | 3.3 |
| poly (acrylic acid)(300Å) | 4.4 | 3.7 | 7.0 | 5.0 |
| PAM-carboxy | — | — | — | 0.04 |
| polyvinylpyrrolidone | 6.3 | 1.0 | 1.3 | 0.6 |
| polystyrene (aq. emulsion) | 6.1 | 0.6 | 0.8 | 0.4 |
| *Best device from 5-10 devices | | | | |
| **Concentrated (i.e., after making the blend solution, some solvent was removed | | | | |
| # to make the solution more viscous, and thereby provide a thicker film). | | | | |

### Example 18

The device measurements summarized in Example 14 were repeated, but the PANI(ES) layer was spin-cast from the blend solutions with different PANI(ES)PAAMPSA/PAM ratios (see EXAMPLE 11). Table 5 shows the device performance of LEDs fabricated from polyblend films with different PANI-PAAMPSA/PAM ratios.

The higher efficiency correlates well with higher resistance in the PANI(ES)(ES)-blend layer. The higher efficiency is obtained with the higher resistance in the PANI(ES)(ES)-blend layer because there is no wasted current due to inter-pixel current leakage.

TABLE 5
Performance of devices fabricated different PANI(ES) blends #

| PANI(ES)PAAMPSA/PAM | Performance at 8.3 mA/cm² | | | |
|---|---|---|---|---|
| (w/w) | V | QE (%) | cd/A | Lm/W |
| 1/9 | 9.1 | 5.0 | 10.7 | 3.7 |
| 1/3 | 5.6 | 5.0 | 12.6 | 7.1 |
| 1/2 | 5.2 | 4.9 | 13.0 | 7.8 |
| 1/1.5 | 5.2 | 4.8 | 12.1 | 7.3 |
| 1/0 | 4.6 | 4.4 | 11.6 | 8.0 |

### Example 19

The device measurements summarized in Example 14 were repeated, but poly[5-(4-(3,7-dimethyloctyloxy)phenyl)-phenylene-1,4-vinylene] (DMOP-PPV) and its random co-polymer with DMO-PPV were used instead of DMO-PPV. The device performance data are listed in Table 6.

This EXAMPLE demonstrates that different color (e.g. red, green, orange etc) can be fabricated using PANI-PAAMPSA as the hole injection layer.

TABLE 6
Device performance of different luminescent
polymer on PANT(ES)-PAAMPSA electrode

| Polymer | | | | Device* | | |
|---|---|---|---|---|---|---|
| Composition | | EL peak | | performance | | |
| (DMOP-PPV)ₙ- | | position | | lumi- | effi- | |
| (DMO-PPV)ₘ | | | V | -nance | ciency | |
| n | m | (nm) | (V) | (cd/m2) | (%) | color |
| 100 | 0 | 510 | 5.3 | 47 | 1.2 | green |
| 98 | 2 | 530 | 4.8 | 130 | 3.2 | yellowish-green |
| 50 | 50 | 580 | 6.6 | 198 | 4.9 | orange |
| 0 | 100 | 610 | 3.3 | 160 | 3.9 | red |

*at current density of 8.3 mA/cm²

### Example 20

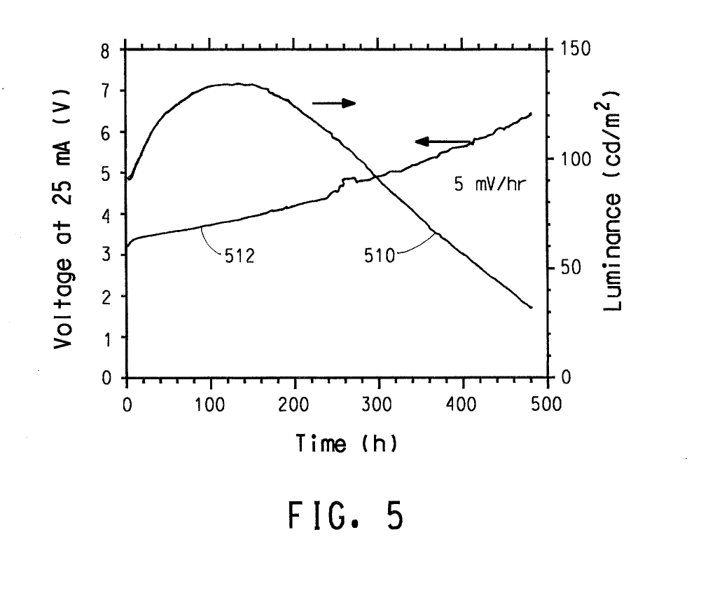

The device of Example 14 was encapsulated using a cover glass sandwiched by UV curable epoxy. The encapsulated devices were run at a constant current of 8.3 mA/cm² in ambient atmosphere in an oven at temperatures 25, 50, 70 and 85° C. The total current through the devices was 25 mA with luminance of approximatelyapproximately 100 cd/cm². FIG. 5 shows the light output (curve 510) and voltage increase (curve 512) during operation at 85° C. In contrast to devices with ITO as anode, which degrade within 10-20 hours of stress at 85° C., the half life of the devices with the ITO/PAAMPSA bilayer exceeds 450 hours with a very low vohage increase (5 mV/hour). From Ahrennius plots of the luminance decay and voltage increase data collected at 50, 70 and 85° C., the temperature acceleration factor was estimated to be ca. 100. Thus, the extrapolated stress life at room temperature was determined to be approximately 40,000 hours.

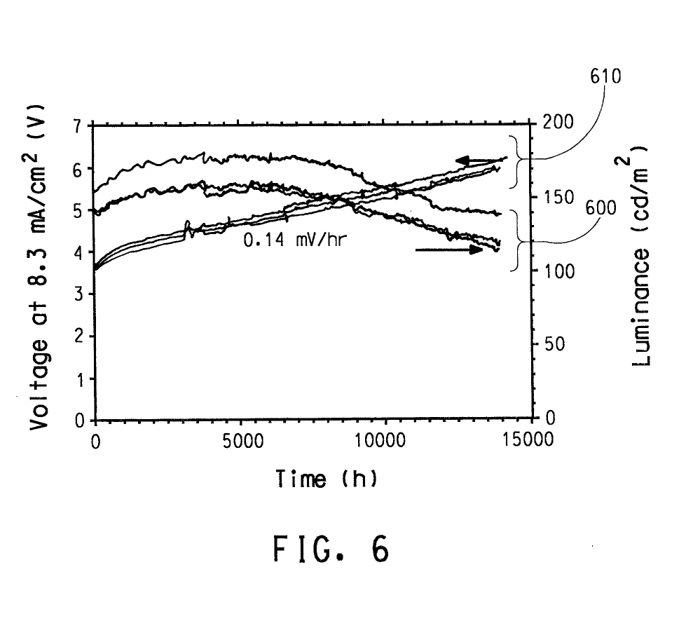

FIG. 6 shows the real time stress data at room temperature light output (curve 600) and voltage increase (curve 610) at the operation at 25° C. As can be seen in FIG. 6, after 10,000 hours stress, the light output has decreased by only approximately 10%. The voltage increase is less than 0.15 mV/hour.

This Example demonstrates that long lifetime can be obtained for polymer LEDS fabricated with high resistance PANI(ES) layers.

### Example 21

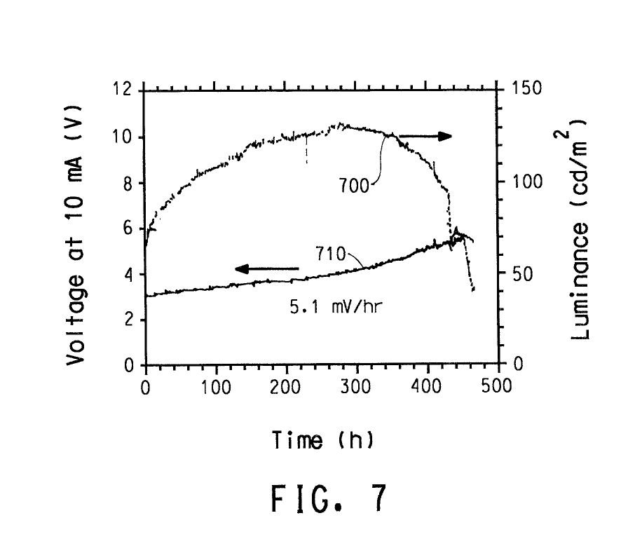

Examples 14 and 20 were repeated, but the higher resistance PANI(ES) PAAMPSA blend (Example 9) was used for the hole injection/layer. FIG. 7 shows the luminance (curve 700) and voltage (at constant current) (curve 710) vs time during stress at 16.5 mA/cm2 with the device at 70° C.

This Example demonstrates that long lifetime, high performance displays can be fabricated using the PANI-PAAMPSA/PAM blend as hole injection layer.

### Example 22

Example 1 was repeated, but 1.7 g of PAM (Polysciences, M.W. 4-6M) was added into aniline-PAAMPSA-water mixture. After vigorous stirring and complete dissolution of PAM in the reaction mixture the oxidant was added into reaction mixture. All other steps were the same as Example 1. A PANI(ES)-blend with polyaniline to PAM ratio of 1:2 was prepared directly from polymerization. Aqueous solutions/dispersions (for example, 1 or 2% w/w) of the final product were prepared by stirring of the resulting powder in deionized water at room temperature for 24 hours in a plastic container. The solution was filtered through a 0.45 μm filter. The bulk conductivity of a thin film spin-cast from the resulting aqueous dispersion was measured to be (approximately 10⁻⁶ S/cm); i.e. three orders of magnitude lower than the film from Example 1 of same thickness; and one order of magnitude lower than that of blend prepared by mixing of aqueous dispersion from Example 1 and PAM solution in water (see Example 5).

This Example demonstrates that the desired high resistance PANI(ES)-PAAMPSA/PAM blend can be synthesized directly in a single process.

### Example 23

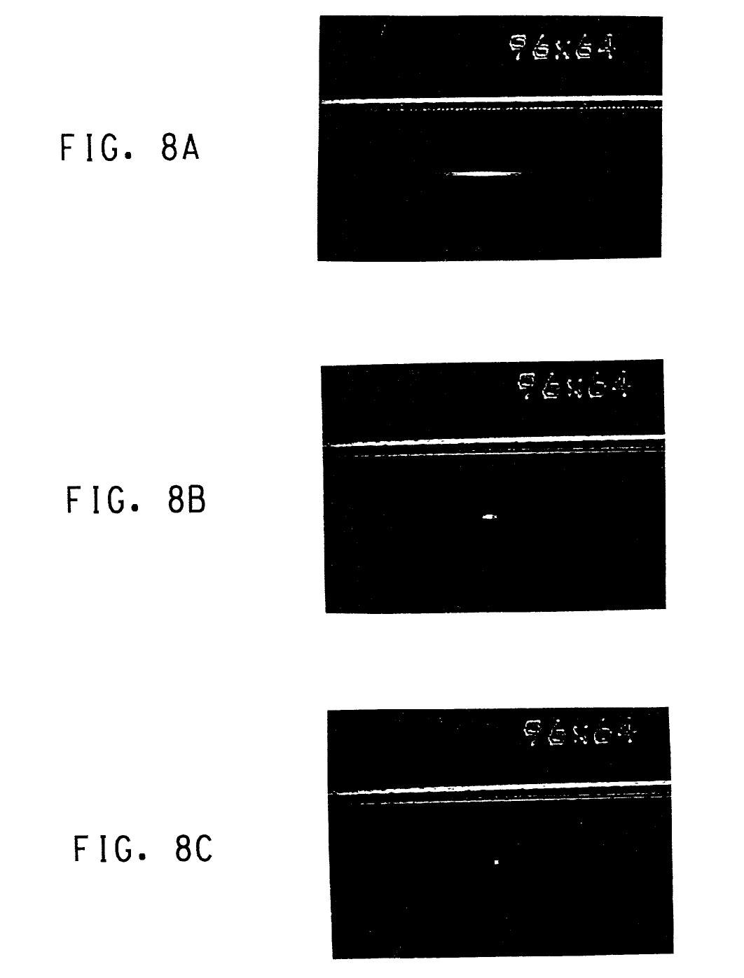

Three passively addressed displays were fabricated, each with 96 rows and 64 columns. The gap between ITO columns was 50 μm. A single pixel was addressed in each display. Photographs of the resulting emission are displayed in FIG. 8. The three displays were identical in every respect except for the resisitivity of the material used for the hole injection layer. The display in FIG. 8a had a low resistance PEDT layer (resistivity approximately equal to 200 ohm-cm) such that the resistance between columns was approximately 20,000 ohms. The display in FIG. 8b had a PANI(ES) polyblend layer (resistivity approximately equal to 4,000 ohm-cm) such that the resistance between columns was approximately 400,000 ohms. The display in FIG. 8c had a higher resistance PANI(ES) polyblend layer (resistivity approximately equal to 50,000 ohm-cm) such that the resistance between columns was approximately 5,000,000 ohms.

As demonstrated in FIG. 8a, with 20,000 ohms between columns, there is significant cross-talk. This cross-talk had two implications:

(i) The resolution and clarity of the display (FIG. 8a) was limited by the cross-talk. Note that the display in FIG. 8b is improved compared to FIG. 8a and the display in FIG. 8c does not exhibit the cross-talk problem.

(ii) The efficiency of the display (FIGS. 8a and 8b) was reduced by the inter-pixel leakage current.

The lower efficiency means that the display required more power than that required in the identical display (FIG. 8c) where the cross-talk was negligible. Because of inter-pixel current leakage, the display shown in FIG. 8a had an efficiency of approximately half that of the display shown in FIG. 8c. The reduction in efficiency due to inter-pixel leakage current can be a factor as large 3-5 times depending on the detailed inter-pixel spacing and pixel size. Using these data, it was estimated that displays fabricated with a PANI(ES) polyblend layer with resistivity in range from 10⁴ ohm-cm to 10⁵ ohm-cm will not be subject to reduced efficiency from inter-pixel leakage current.

This Example demonstrates the importance of using high resistance hole injection layer in passively addressed polymer LED displays.

What is claimed is:

1. In an electronic device comprising a photoactive layer comprising a photoactive organic material between a hole-injecting anode and an electron-injecting cathode, and a layer of conductive organic polymer having a resistivity of at least about 10⁴ ohms-cm between the anode and the photoactive layer.

2. The device of claim 1, wherein the high resistivity layer has a resistivity of at least about 10⁵ ohms-cm, preferably at least about 10⁶ ohms-cm.

3. The device of claim 1, wherein the high resistivity layer comprises polyaniline.

4. The device of claim 1, wherein the high resistivity layer comprises polyaniline plus functionalized sulfonic acid.

5. The device of claim 1, wherein the high resistivity layer additionally comprises a host polymer.

6. The device of claim 1, wherein the high resistivity layer comprises polyaniline in emeraldine salt form.

7. The device of claim 1, wherein the anode is a patterned ITO layer.

8. A method for making an electronic device, the steps comprising:
depositing a high resistivity layer of conductive organic polymer onto an anode, wherein the high resistivity layer of conductive organic polymer has a resistivity of at least about 10⁴ ohms-cm;
depositing a photoactive layer comprising a photoactive organic material on the high resistivity layer; and
depositing an electron-injecting cathode on the photactive layer.

9. The method of claim 8, wherein the high resistivity layer has a resistivity of at least about 10⁵ ohms-cm, preferably at least about 10⁶ ohms-cm.

10. The method of claim 8, wherein the high resistivity layer comprises polyaniline.

11. The method of claim 8, wherein the high resistivity layer comprises polyaniline plus functionalized sulfonic acid.

12. The method of claim 8, wherein the high resistivity layer additionally comprises a host polymer.

13. The method of claim 8, wherein the high resistivity layer comprises polyaniline in emeraldine salt form.

14. The method of claim 8, wherein the anode is a patterned ITO layer.

15. The method of claim 8, wherein the depositing of a high resistivity layer carried out using an aqueous solution comprising the conductive organic polymer.

16. The device of claim 1, wherein the device is selected from a photodetecting device or a emissive display device.
